(19) United States
(12) Patent Application Publication
(10) Pub. No.: US 2020/0358030 A1
(43) Pub. Date: Nov. 12, 2020

(54) DISPLAY DEVICE

(71) Applicant: Sharp Kabushiki Kaisha, Sakai City, Osaka (JP)

(72) Inventors: Tohru OKABE, Sakai City (JP); Ryosuke GUNJI, Sakai City (JP); Hiroki TANIYAMA, Sakai City (JP); Shinsuke SAIDA, Sakai City (JP); Shinji ICHIKAWA, Sakai City (JP); Akira INOUE, Yonago-shi (JP); Hiroharu JINMURA, Yonago-shi (JP); Yoshihiro NAKADA, Yonago-shi (JP)

(21) Appl. No.: 16/640,424

(22) PCT Filed: Aug. 24, 2017
(86) PCT No.: PCT/JP2017/030333

§ 371 Date: Feb. 20, 2020

(51) Int. Cl. H01L 51/52; H01L 27/32

(52) U.S. Cl. CPC H01L 51/5253; H01L 51/0097; H01L 27/3246

(57) ABSTRACT

A frame-like bank 35 has two inclined side surfaces, at least one of which forms a taper angle θ2 of not more than 20°. A first sealing film 28, which is an inorganic film, is formed in a display area DA and a non-display area NDA in a manner so as to cover the frame-like bank 35.

### TECHNICAL FIELD

The disclosure relates to, for example, a display device including a display element such as an organic EL display element.

### BACKGROUND ART

Recently, various flat-panel displays have been developed. In particular, electroluminescent (EL) display devices such as (i) organic EL display devices including an organic light emitting diodes (OLEDs) and (ii) inorganic EL display devices including inorganic light emitting diodes have been a focus of attention because they achieve improved image quality and power savings.

Furthermore, because display devices such as EL display devices which do not require a backlight can be flexed freely, there has been much research aimed at achieving flexible display devices.

Organic light emitting diodes and inorganic light emitting diodes which serve as display elements in devices such as EL display devices have reliability problems. For example, ingress of foreign substances such as water and oxygen can shorten the lives of such display elements. As such, in order to prevent the ingress of foreign substances such as water and oxygen, the display elements include a sealing film which covers the display element.

### CITATION LIST

### Patent Literature

[Patent Literature 1]

Japanese Patent Application Publication, Tokukai, No. 2004-198486 (Publication Date: Jul. 15, 2004)

[Patent Literature 2]

International Publication No. WO 2012/049716 (Publication Date: Apr. 19, 2012)

### SUMMARY

### Technical Problem

Unfortunately, flexible display devices such as flexible EL display devices which can be flexed freely have problems with ensuring reliability. This because the sealing film, which is provided to prevent ingress of foreign substances such as water and oxygen into display elements, can become separated from an underlying base film due to frequent flexing of the display device.

An embodiment of the disclosure has been made in view of the above problem. An object of the disclosure is to provide a display device having high reliability.

### Solution to Problem

In order to solve the above problem, a display device in accordance with an embodiment of the disclosure includes: a substrate having (i) a display area in which an active element and a display element are provided and (ii) a non-display area which is provided outside the display area; one or more inorganic films being provided in the display area and the non-display area in a manner so as to cover a semiconductor layer of the active element; a frame-like bank which (i) is made from an organic material, (ii) is provided in the non-display area, above the one or more inorganic films, in a manner so as to surround the display area, and (iii) has two inclined side surfaces, at least one of which forms a taper angle of not more than 20°; and a first sealing film, which is an inorganic film, being provided in the display area and the non-display area in a manner so as to cover the frame-like bank.

The first sealing film, which is an inorganic film, is provided in order to prevent ingress of foreign substances such as water and oxygen into the display element. With the above configuration, the first sealing film is provided so as to cover the frame-like bank, which is made from an organic material and has at least one inclined side surface that forms a taper angle of not more than 20°. As such, the above configuration achieves an increase in the area of contact between the first sealing film and the frame-like bank. This makes it possible to prevent or reduce separation of the first sealing film from the frame-like bank, which separation is caused by frequent flexing of the display device. The above configuration therefore makes it possible to achieve a display device having high reliability.

In order to solve the above problem, a display device in accordance with an embodiment of the disclosure includes: a substrate having (i) a display area in which an active element and a display element are provided and (ii) a non-display area which is provided outside the display area; one or more inorganic films being provided in the display area and the non-display area in a manner so as to cover a semiconductor layer of the active element; a frame-like bank which (i) is made from an organic material, (ii) is provided in the non-display area, above the one or more inorganic films, in a manner so as to surround the display area, and (iii) has two inclined side surfaces; and a first sealing film, which is an inorganic film, being provided in the display area and the non-display area in a manner so as to cover the frame-like bank, a depression being formed in the one or more inorganic films at an edge of at least one of the two inclined side surfaces, the first sealing film conforming to the depression.

The first sealing film, which is an inorganic film, is provided in order to prevent ingress of foreign substances such as water and oxygen into the display element. With the above configuration, the first sealing film is provided so as to (i) cover the frame-like bank, which is made from an organic material, and (ii) conform to the depression formed in the one or more inorganic films. As such, the above configuration achieves an increase in the area of contact between the first sealing film and the one or more inorganic films. This makes it possible to prevent or reduce separation of the first sealing film from the frame-like bank, which separation is caused by frequent flexing of the display device. The above configuration therefore makes it possible to achieve a display device having high reliability.

### Advantageous Effects of Invention

An aspect of the disclosure makes it possible to provide a display device having high reliability.

### BRIEF DESCRIPTION OF DRAWINGS

FIG. 1 is a diagram schematically illustrating a flexible organic EL display device which is a comparative example.

FIG. 2 is a plan view schematically illustrating a display device. The display device includes a plurality of the flexible organic EL display devices illustrated in FIG. 1, which are provided on a base substrate. FIG. 2 shows the display device in a state prior to being divided into individual pieces.

FIG. 3 is a diagram schematically illustrating a frame-like bank which is provided in a non-display area of the flexible organic EL display device illustrated in FIG. 1.

FIG. 4 a flexible organic EL display device in accordance with Embodiment 1, which differs from the non-display area of the flexible organic EL display device of FIG. 1 by including, instead of the frame-like bank of FIG. 3, a frame-like bank having at least one inclined side surface that forms a taper angle of not more than 20°.

FIG. 5 is a plan view schematically illustrating a display device. The display device includes a plurality of the flexible organic EL display devices illustrated in FIG. 4, each of which (i) is provided on a base substrate and (ii) has a frame-like bank which has at least one inclined side surface that forms a taper angle of not more than 20°. FIG. 5 shows the display device in a state prior to being divided into individual pieces.

FIG. 6 is a diagram schematically illustrating a flexible organic EL display device in accordance with Embodiment 2, which includes a depression having at least one inclined side surface, the depression being provided at an edge of an inclined side surface of the frame-like bank illustrated in FIG. 3.

FIG. 7 is a diagram schematically illustrating a variation of the flexible organic EL display device of Embodiment 2 illustrated in FIG. 6.

FIG. 8 is a diagram schematically illustrating a flexible organic EL display device in accordance with Embodiment 3, which includes a depression having at least one inclined side surface. The depression is provided at an edge of an inclined side surface of the frame-like bank illustrated in FIG. 4.

FIG. 9 is a diagram schematically illustrating a flexible organic EL display device in accordance with Embodiment 4, which includes a depression having at least one step-like side surface. The depression is provided at an edge of an inclined side surface of the frame-like bank illustrated in FIG. 3.

FIG. 10 is a diagram schematically illustrating a flexible organic EL display device in accordance with Embodiment 5, which includes a depression having at least one step-like side surface. The depression is provided at an edge of an inclined side surface of the frame-like bank illustrated in FIG. 4.

FIG. 11 is a diagram schematically illustrating a flexible organic EL display device in accordance with Embodiment 6, which includes (i) the frame-like bank illustrated in FIG. 3, (ii) a frame-like bank having at least one inclined side surface that forms a taper angle of not more than 20°, and (iii) a depression having at least one inclined side surface. The depression is provided at an edge of the inclined side surface of the frame-like bank illustrated in FIG. 3.

### DESCRIPTION OF EMBODIMENTS

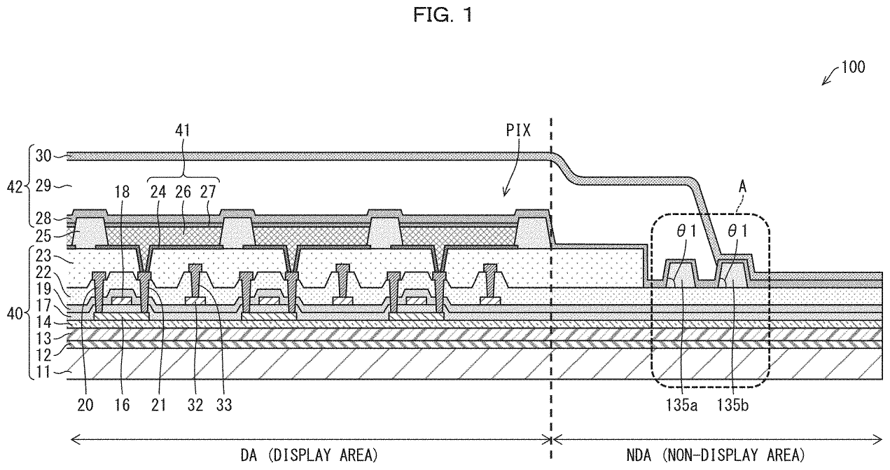

The following descriptions will discuss embodiments of the disclosure with reference to FIGS. 1 to 11. In the following descriptions, for convenience of description, members having functions identical to those described in a certain embodiment may be assigned identical referential numerals and their descriptions may be omitted.

The embodiments described below involve examples in which an organic electroluminescent (EL) device serves as one example of a display element (optical element). Note, however, that the disclosure is not limited to such examples. For example, the display element may be a reflective liquid crystal display element which does not require a backlight and whose luminance and transmittance are controlled by voltage.

The display element (optical element) may be an optical element whose luminance or transmittance is controlled by current. For example, there are EL (electroluminescent) displays such as (i) organic EL displays including organic light emitting diodes (OLEDs) as current-controlled optical elements and (ii) inorganic EL displays including inorganic light emitting diodes as current-controlled optical elements, and quantum dot light emitting diode (QLED) displays including QLEDs as current-controlled optical elements.

### Embodiment 1

With reference to FIGS. 1 to 3, discussed first are (i) a basic configuration of a flexible organic EL display device 100, which is a comparative example, and (ii) problems with the flexible organic EL display device 100.

FIG. 1 is a diagram schematically illustrating the flexible organic EL display device 100, which is a comparative example. The flexible organic EL display device 100 includes frame-like banks 135a and 135b each having inclined side surfaces, the inclined side surfaces each forming a taper angle θ1 that is greater than 40°.

As illustrated in FIG. 1, the flexible organic EL display device 100 has a region subjected to thin film encapsulation (TFE) and a region not subjected to thin film encapsulation.

The flexible organic EL display device 100 includes a driving circuit (not illustrated) in the region not subjected to thin film encapsulation.

Note that the flexible organic EL display device 100 may include a touch panel (not illustrated).

The flexible organic EL display device 100 includes a film substrate serving as a flexible substrate 11 in order to enable bending of the display device. Note, however, that in cases where bending is unnecessary, a glass substrate (inflexible substrate) may be used.

The flexible organic EL display device 100 is produced using a laser lift off process (also known as a “LLO process”) to provide flexibility. First, formation of, for example, an active element (such as a TFT element) is carried out on highly heat-resistant inflexible substrate (such as a glass substrate) in a high-temperature step. Thereafter, a laser beam is irradiated from a glass substrate side. The laser causes ablation at an interface between (i) the glass substrate and (ii) a polyimide layer (PI layer) which is a resin layer formed on the glass substrate. The glass substrate is then removed from the polyimide layer (PI layer), and a film substrate (the flexible substrate 11) is affixed to the polyimide layer (PI layer) via an adhesive layer. Note however, that this is a non-limiting example.

The flexible organic EL display device 100 illustrated in FIG. 1 is produced with use of an LLO process and therefore includes, on the film substrate (flexible substrate 11), an adhesive layer 12, a polyimide layer (PI layer) 13 which is a resin layer, and a moisture-proof layer 14. However, in the case of a flexible organic EL display device whose production does not involve an LLO process, the adhesive layer 12 and the PI layer 13 may be omitted.

The flexible organic EL display device 100 has a display area (DA) in which a TFT element (active element) and an organic EL element 41 are provided. The TFT element includes a semiconductor layer 16, a gate insulating film 17, a gate electrode 18, a first interlayer film 19, a second interlayer film 22, a source electrode 20, a drain electrode 21, and an organic interlayer film 23. The organic EL element 41 serves as a display element and is electrically connected to the TFT element.

As illustrated, the organic EL element 41 includes (i) a first electrode 24, which is electrically connected to the drain electrode 21 of the TFT element, (ii) a layer 26 including a light emitting layer, and (iii) a second electrode 27.

An edge cover 25 is provided in a manner so as to cover an edge of the first electrode 24. A region surrounded by this edge cover 25 forms one pixel PIX.

The layer 26 including the light emitting layer may have a configuration in which, for example, a hole injection layer, a hole transport layer, the light emitting layer, an electron transport layer, and an electron injection layer are disposed in this order, starting from a first electrode 24 side.

Note that “TFT substrate 40” collectively refers to the following: the flexible substrate 11; the adhesive layer 12; the PI layer 13; the moisture-proof layer 14; the semiconductor layer 16; the gate insulating film 17; the gate electrode 18; the first interlayer film 19; a capacitor electrode 32 which opposes a capacitor counter electrode (not illustrated) and is provided in the same layer as the gate electrode 18; the second interlayer film 22; the source electrode 20, the drain electrode 21, and wiring 33 of the capacitor electrode 32, which are provided in the same layer; and the organic interlayer film 23.

The moisture-proof layer 14 is a layer for preventing, for example, moisture and impurities from reaching, for example, the TFT element and the organic EL element 41 when the flexible organic EL display device 100 is used. The moisture-proof layer 14 can be constituted by, for example, (i) a silicon oxide film formed by CVD, (ii) a silicon nitride film formed by CVD, (iii) a silicon oxynitride film formed by CVD, or (iv) a laminated film made up of these films.

The semiconductor layer 16 can be constituted by, for example, low-temperature polysilicon (LTPS) or an oxide semiconductor. The gate insulating film 17 can be constituted by, for example, a silicon oxide (SiOx) film formed by CVD, a silicon nitride (SiNx) film formed by CVD, or a laminated film made up of these films.

The gate electrode 18, the source electrode 20, the drain electrode 21, the capacitor counter electrode (not illustrated), the capacitor electrode 32, and the wiring 33 of the capacitor electrode 32 can each be constituted by, for example, a single-layer metal film or a laminated metal film, including at least one of the following: aluminum (Al), tungsten (W), molybdenum (Mo), tantalum (Ta), chromium (Cr), titanium (Ti), and copper (Cu).

The first interlayer film 19 and the second interlayer film 22 can each be constituted by, for example, a silicon oxide (SiOx) film formed by CVD, a silicon nitride (SiNx) film formed by CVD, or a laminated film made up of these films.

The organic interlayer film 23 can be constituted by, for example, a photosensitive organic material, such as polyimide or acrylic, which can be applied to a surface.

The first electrode (for example, positive electrode) 24 can be constituted by, for example, a stack of a layer of indium tin oxide (ITO) and a layer of an Ag-containing alloy. The first electrode has light reflectivity. The second electrode (for example, negative electrode) 27 can be constituted by, for example, a transparent metal such as indium tin oxide (ITO) or indium zincum oxide (IZO).

The edge cover 25 can be constituted by, for example, a photosensitive organic material, such as polyimide or acrylic, which can be applied to a surface.

The flexible organic EL display device 100 includes a sealing layer 42 which covers at least the organic EL element 41.

The sealing layer 42 is a laminated film which covers the organic EL element 41. The sealing layer 42 includes (i) a first sealing film 28, which is an inorganic film, (ii) a second sealing layer 29, which is an organic film, and (iii) a third sealing film 30, which is an inorganic film, the first through third sealing films being disposed in this order, starting from a TFT substrate 40 side.

The sealing layer 42 achieves thin film encapsulation (TFE) of the organic EL element 41 and thereby prevents deterioration of the organic EL element 41 which could be otherwise caused by ingress of, for example, moisture and oxygen from outside.

The first sealing film 28 and the third sealing film 30, which are inorganic films, have a moisture-proofing function to prevent ingress of moisture. The first sealing film 28 and the third sealing film 30 prevent deterioration of the organic EL element 41 which could otherwise be caused by, for example, moisture and oxygen.

The second sealing layer 29, which is an organic film, serves to, for example, (i) mitigate stress in the first sealing film 28 and the third sealing film 30, which are inorganic films having high film stress, (ii) fill in uneven portions in the surface of the organic EL element 41 so as to achieve planarization, (iii) fill in pinholes, or (iv) prevent or reduce cracks and film separation from occurring when inorganic films are provided.

Note however that the above laminated structure is only one example. The sealing layer 42 is not limited to a three-layer structure. The sealing layer 42 may have a laminated structure in which the total number of inorganic and organic layers is four or more, provided that the first sealing film 28, which is an inorganic film, is the bottommost layer.

Examples of materials for the second sealing layer 29, which is an organic film, include organic insulating materials (resin materials) such as polysiloxane, silicon oxycarbide (SiOC), acrylate, polyurea, parylene, polyimide, and polyamide.

Examples of materials for the first sealing film 28 and the third sealing film 30, which are inorganic films, include inorganic insulating materials such as silicon nitride, silicon oxide, silicon oxynitride, and Al₂O₃.

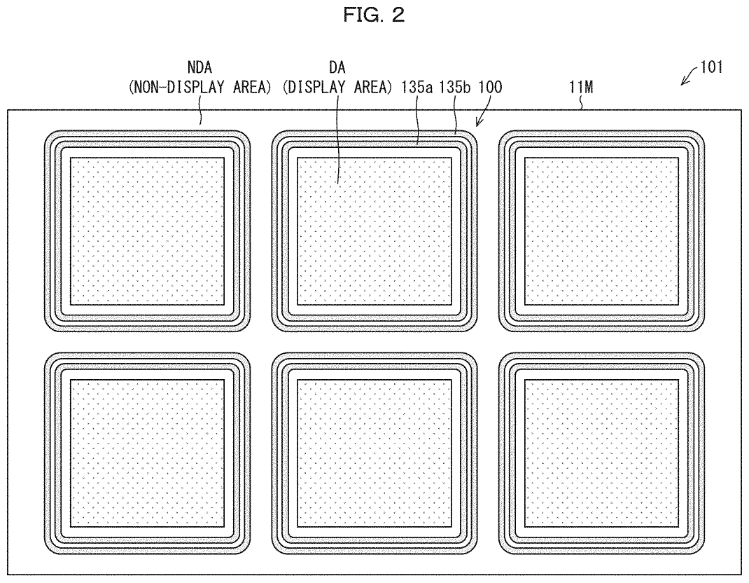

FIG. 2 is a plan view schematically illustrating a display device 101. The display device 101 includes a plurality of the flexible organic EL display devices 100 illustrated in FIG. 1, which are provided on a base substrate 11M that is flexible. FIG. 2 shows the display device 101 in a state prior to being divided into individual pieces.

As illustrated in FIGS. 1 and 2, a non-display area (NDA) (also called a frame region) is provided outward of the display area (DA) of the flexible organic EL display device 100. A first frame-like bank 135a is provided above the second interlayer film 22 (one or more inorganic films which cover the semiconductor layer 16), in an area which is in the vicinity of the edge of the organic interlayer film 23 in the non-display area (NDA). The first frame-like bank 135a surrounds the display area (DA). A second frame-like bank 135b is provided so as to surround the first frame-like bank 135a.

The first frame-like bank 135a and the second frame-like bank 135b are each made from an organic material and have inclined side surfaces. Each of the inclined side surfaces forms a taper angle θ1 that is greater than 40° (θ1>40°). In the present comparative example, the taper angle θ1 is 60°.

In a process for forming the second sealing layer 29 of the sealing layer 42, a liquid organic material is applied at least to the entirety of the display area (DA). The first frame-like bank 135a and the second frame-like bank 135b prevent the liquid organic material from spreading.

In the configuration illustrated in FIG. 1, the second sealing layer 29 is formed so as to reach the inclined side surface on the left side of the second frame-like bank 135b. As such, in a region outward of the inclined side surface on the left side of the second frame-like bank 135b, the first sealing film 28 and the third sealing film 30, which are inorganic films, are in direct contact with each other and form a sealing layer.

The first frame-like bank 135a and the second frame-like bank 135b can be constituted by, for example, a photosensitive organic material, such as polyimide or acrylic, which can be applied to a surface.

Each of the first frame-like bank 135a and the second frame-like bank 135b can be formed from the same material as the edge cover 25. It is also possible to form each of the first frame-like bank 135a, the second frame-like bank 135b, and the edge cover 25 from the same material and in the same step. The disclosure is not limited to this, however, and it is possible to form these members from different materials and in different steps.

Note that the first frame-like bank 135a, the second frame-like bank 135b, and the edge cover 25 can be formed by patterning by e.g. photolithography.

The second sealing layer 29 is preferably applied and formed by an ink jet method, but this is a non-limiting example.

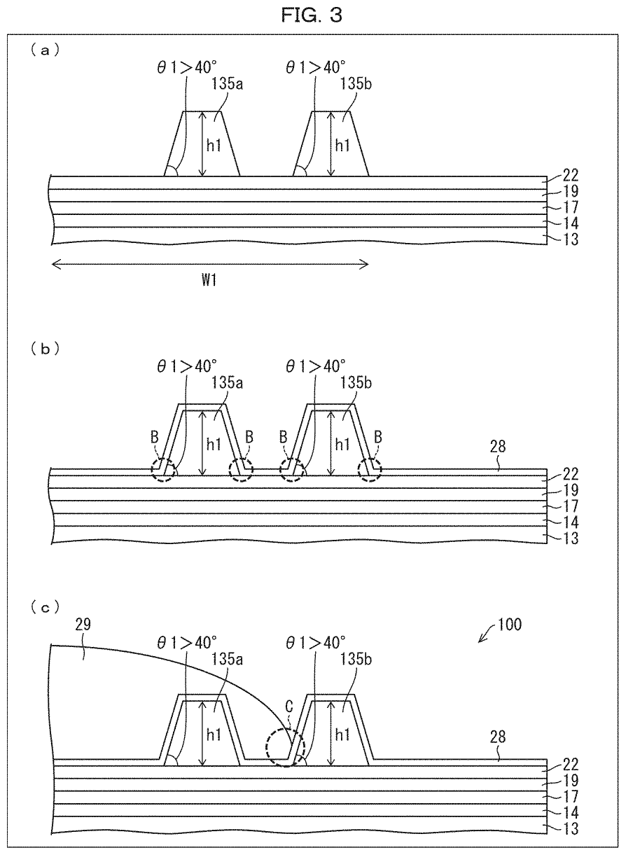

(a) of FIG. 3 is a diagram illustrating a state prior to formation of the sealing layer 42. (b) of FIG. 3 is a diagram illustrating a state in which the first sealing film 28 of the sealing layer 42 has been formed. (c) of FIG. 3 is a diagram illustrating a portion A of the flexible organic EL display device 100 as indicated by the dotted line in FIG. 1. Specifically, (c) of FIG. 3 illustrates a state where the first sealing film 28, the second sealing layer 29, and a third sealing film 30 (not illustrated) which constitute the sealing layer 42 have been formed.

As illustrated in FIG. 1 and (a) of FIG. 3, the first frame-like bank 135a and the second frame-like bank 135b are provided within a distance W1 (250 μm) as measured from an edge of the organic interlayer film 23 in the non-display area (NDA). Each of the first frame-like bank 135a and the second frame-like bank 135b has two inclined side surfaces, the inclined side surfaces each forming a taper angle θ1 that is greater than 40° (θ1>40°). Each of the first frame-like bank 135a and the second frame-like bank 135b has a height h1 that is set so as to be sufficient to regulate spreading of a liquid organic material.

As illustrated in (b) of FIG. 3, the first sealing film 28, which is an inorganic film, is formed so as to cover (i) the first frame-like bank 135a and second frame-like bank 135b, which are both made from an organic material and have inclined side surfaces that each form a taper angle greater than 40°, and (ii) the second interlayer film 22 which is an inorganic film. With such a configuration, the contact between (i) the first frame-like bank 135a and the second frame-like bank 135b and (ii) the first sealing film 28 is contact between inorganic and organic films, and therefore does not have a strong force of adhesion. Furthermore, because the first frame-like bank 135a and the second frame-like bank 135b have inclined side surfaces each forming a taper angle greater than 40°, there is not sufficient area of contact between (i) the first frame-like bank 135a and the second frame-like bank 135b and (ii) the first sealing film 28.

For these reasons, the first sealing film 28 is prone to separation caused by, for example, frequent flexing of the flexible organic EL display device 100. Specifically, the first sealing film 28 is prone to such separation at places where the underlying base film (second interlayer film 22, first frame-like bank 135a, and second frame-like bank 135b) changes from an inorganic film to an organic film or vice versa, as seen in the portions B indicated by dotted lines in (b) of FIG. 3.

(c) of FIG. 3 illustrates a configuration in which e.g. the second sealing layer 29 and the third sealing film 30 (not illustrated) are provided above such places where the first sealing film 28 is prone to separation. However, even with such a configuration, ingress of e.g. moisture and oxygen occurs at places where the first sealing film 28 separates from the underlying base film. As such, a sufficiently reliable flexible organic EL display device cannot be achieved with the flexible organic EL display device 100 (comparative example), which includes the first frame-like bank 135a and the second frame-like bank 135b, each having two inclined side surfaces forming a taper angle θ1 greater than 40° (θ1>40°).

The flexible organic EL display device 100 is achieved as follows. Steps up to and including a step of forming the first sealing film 28, the second sealing layer 29, and the third sealing film 30 (not illustrated) which constitute the sealing layer 42 are carried out on an inflexible glass substrate (not illustrated). After the first sealing film 28, the second sealing layer 29, and the third sealing film 30 are formed, an LLO process is carried out in which the inflexible glass substrate is removed from the PI layer 13, and a flexible film substrate (not illustrated) is affixed to the PI layer 13 via an adhesive layer (not illustrated).

The inventors of the disclosure achieved a flexible organic EL display device 1 which has high reliability and prevents or reduces separation of the first sealing film 28 from an underlying base film, by providing a frame-like bank 35 having at least one inclined side surface that forms a taper angle θ2 of not more than 20° (θ2≤20°).

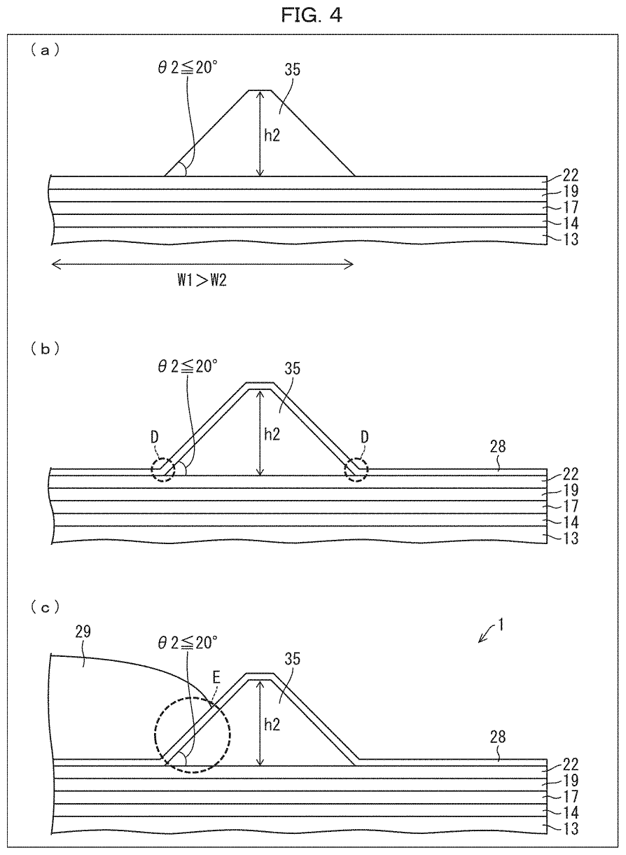

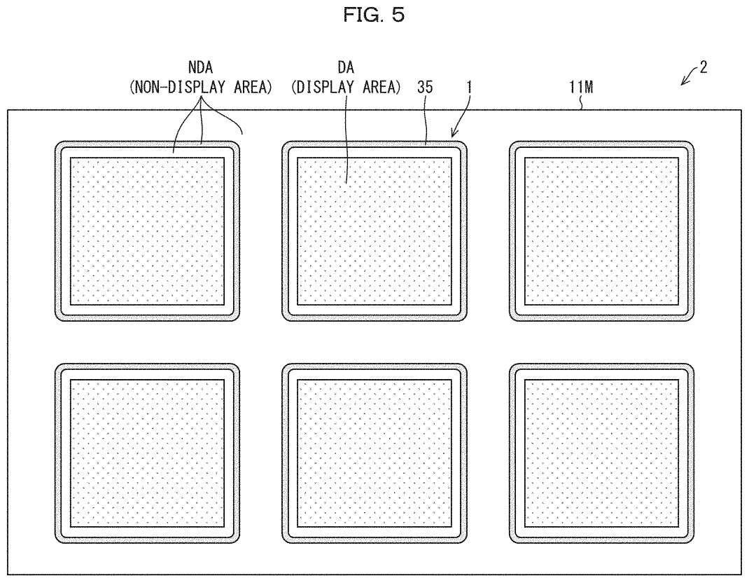

The following description will discuss an embodiment of the disclosure with reference to FIGS. 4 and 5. Embodiment 1 differs from the above comparative example (discussed with reference to FIGS. 1 to 3) in that Embodiment 1 includes the frame-like bank 35 having at least one inclined side surface that forms a taper angle θ2 of not more than 20° (θ2≤20°). Aside from this difference, the present embodiment is similar to the comparative example. For convenience of description, members of the present embodiment which are identical in function to members illustrated in the drawings for the comparative example are assigned the same reference signs, and descriptions of such members will be omitted.

FIG. 4 is a diagram schematically illustrating the flexible organic EL display device 1. The flexible organic EL display device 1 includes the frame-like bank 35 having at least one inclined side surface that forms a taper angle of not more than 20°.

(a) of FIG. 4 is a diagram illustrating a state prior to formation of a sealing layer 42. (b) of FIG. 4 is a diagram illustrating a state in which a first sealing film 28 of the sealing layer 42 has been formed. (c) of FIG. 4 is a diagram illustrating a state where the first sealing film 28, a second sealing layer 29, and a third sealing film 30 (not illustrated) which constitute the sealing layer 42 have been formed.

The flexible organic EL display device 1 is achieved as follows. Steps up to and including a step of forming the first sealing film 28, the second sealing layer 29, and the third sealing film 30 (not illustrated) which constitute the sealing layer 42 are carried out on an inflexible glass substrate (not illustrated). After the first sealing film 28, the second sealing layer 29, and the third sealing film 30 are formed, an LLO process is carried out in which the inflexible glass substrate is removed from a PI layer 13, and a flexible film substrate (not illustrated) is affixed to the PI layer 13 via an adhesive layer (not illustrated).

FIG. 5 is a plan view schematically illustrating a display device 2. The display device 2 includes a plurality of the flexible organic EL display devices 1 illustrated in FIG. 4, each of which (i) is provided on a base substrate 11M that is a flexible substrate and (ii) has a frame-like bank 35 which has at least one inclined side surface that forms a taper angle of not more than 20°. FIG. 5 shows the display device 2 in a state prior to being divided into individual pieces.

As illustrated in (a) of FIG. 4 and in FIG. 5, the frame-like bank 35 is provided within a distance W2 (100 μm) as measured from an edge of an organic interlayer film 23 (see FIG. 1) in a non-display area (NDA). The distance W2 is less than the distance W1 (250 μm). The frame-like bank 35 has two inclined side surfaces, each forming a taper angle θ2 of not more than 20° (θ2≤20°). The frame-like bank 35 has a height h2 that is set so as to be sufficient to regulate spreading of a liquid organic material. In Embodiment 1, the taper angle θ2 is 20°, and the height h2 is the same as the height h1 of the first frame-like bank 135a and the second frame-like bank 135b in the comparative example. Note, however, that this is a non-limiting example.

The flexible organic EL display device 100, which is a comparative example, includes two frame-like banks (the first frame-like bank 135a and the second frame-like bank 135b), and a space must be provided therebetween. As such, the first frame-like bank 135a and the second frame-like bank 135b are provided within the distance W1 (250 μm) as measured from the edge of the organic interlayer film 23 in the non-display area (NDA).

In contrast, the frame-like bank 35 of Embodiment 1 has two inclined side surfaces each forming a taper angle θ2 of 20°. As such, although the frame-like bank is wider than the first frame-like bank 135a and the second frame-like bank 135b of the comparative examples, only one frame-like bank 35 is formed, unlike the comparative example in which two frame-like banks are formed. The frame-like bank 35 is therefore provided within the distance W2 (100 μm) which is less than the distance W1 (250 μm), as measured from the edge of the organic interlayer film 23 in the non-display area (NDA).

The frame-like bank 35 can be made of the same material as in the comparative example. The inclined side surfaces forming the taper angle θ2 of not more than 20° (θ2≤20° can be formed by patterning by e.g. photolithography with use of e.g. a half-tone mask or a gray tone mask.

As illustrated in (b) of FIG. 4, the first sealing film 28, which is an inorganic film, is formed so as to cover (i) the frame-like bank 35, which is made from an organic material and has the two inclined side surfaces each forming the taper angle θ2 of 20°, and (ii) the second interlayer film 22, which is an inorganic film.

The first sealing film 28 is provided in order to prevent ingress of foreign substances such as water and oxygen into the organic EL element 41. Because the first sealing film 28 is formed so as to cover the frame-like bank 35, which is made from an organic material and has the inclined side surfaces each forming the taper angle of not more than 20°, there is an increase in the area of contact between the first sealing film 28 and the frame-like bank 35. This makes it possible to prevent or reduce separation of the first sealing film 28 from the frame-like bank 35 caused by frequent flexing of the flexible organic EL display device 1, specifically separation at places where an underlying base film (second interlayer film 22, frame-like bank 35) changes from an inorganic film to an organic film or vice versa, as seen in the portions D indicated by dotted lines in (b) of FIG. 4.

In this way, separation of the first sealing film 28 from the frame-like bank 35 is prevented or reduced as seen in the portions D indicated by the dotted lines in (b) of FIG. 4. This makes it possible to prevent or reduce separation of the first sealing film 28 also at the portion E indicated by dotted lines in (c) of FIG. 4. As such, providing the second sealing layer 29 and the third sealing film 30 (not illustrated) above the first sealing film 28 makes it possible to achieve the flexible organic EL display device 1 having even higher reliability.

Discussed in Embodiment 1 is an example in which the frame-like bank 35 has two inclined side surfaces each of which forms the taper angle θ2 of not more than 20° (θ2≤20°. Note, however, that this is a non-limiting example. It is possible to employ a frame-like bank in which only one of the two inclined side surfaces (either the inclined side surface closer to the display area (DA) or the display area (DA) farther from the display area (DA)) forms a taper angle θ2 of not more than 20° (θ2≤20°).

Discussed in Embodiment 1 is an example in which the height h2 of the frame-like bank 35 is the same as the height h1 of the first frame-like bank 135a and the second frame-like bank 135b. Note, however, that this is a non-limiting example. The height h2 of the frame-like bank 35 need only be equal to or greater than the height h1 of the first frame-like bank 135a and the second frame-like bank 135b (h2 h1).

In particular, the frame-like bank 35 is provided within the distance W2 (100 μm) as measured from the edge of the organic interlayer film 23 in the non-display area (NDA), which distance W2 is less than the distance W1 (250 μm). Increasing the distance makes it possible to ensure that the height h2 is sufficient.

### Embodiment 2

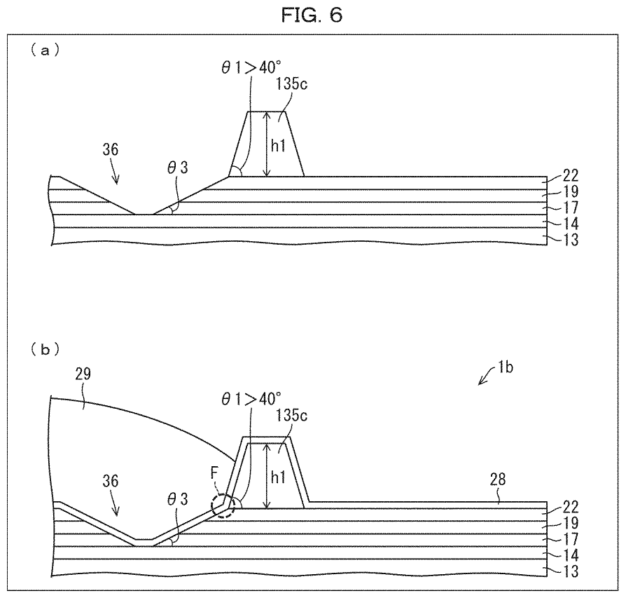

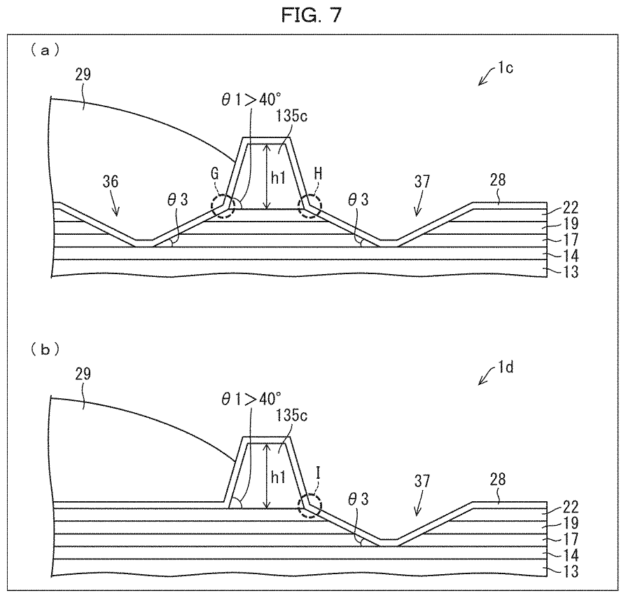

Next, the following description will discuss Embodiment 2 of the disclosure with reference to FIGS. 6 and 7. Embodiment 2 differs from Embodiment 1 in that the configuration of Embodiment 2 includes (i) a frame-like bank 135c having two inclined side surfaces each forming a taper angle θ1 greater than 40° (θ1>40°) and (ii) depressions 36 and/or 37 which are formed in one or more inorganic films, at an edge of an inclined side surface of the frame-like bank 135c. The depressions 36 and 37 each have at least one inclined side surface that forms a taper angle θ3. Other than these differences, Embodiment 2 is similar to Embodiment 1. For convenience of description, members of the present embodiment which are identical in function to members illustrated in the drawings for Embodiment 1 are assigned the same reference signs, and descriptions of such members will be omitted.

FIG. 6 is a diagram schematically illustrating a flexible organic EL display device 1b including the depression 36. The depression 36 is provided at the edge of the inclined side surface of the frame-like bank 135c which inclined side surface is closer to the display area (DA). The depression 36 has at least one inclined side surface that forms the taper angle θ3.

(a) of FIG. 6 is a diagram illustrating a state prior to formation of a sealing layer 42. (b) of FIG. 6 is a diagram illustrating a state where a first sealing film 28, a second sealing layer 29, and a third sealing film 30 (not illustrated) which constitute the sealing layer 42 have been formed.

The flexible organic EL display device 1b is achieved as follows. Steps up to and including a step of forming the first sealing film 28, the second sealing layer 29, and the third sealing film 30 (not illustrated) which constitute the sealing layer 42 are carried out on an inflexible glass substrate (not illustrated). After the first sealing film 28, the second sealing layer 29, and the third sealing film 30 are formed, an LLO process is carried out in which the inflexible glass substrate is removed from a PI layer 13, and a flexible film substrate (not illustrated) is affixed to the PI layer 13 via an adhesive layer (not illustrated).

As illustrated in (a) of FIG. 6, the depression 36, having the at least one inclined side surface that forms the taper angle θ3, is formed at an edge of the inclined side surface of the frame-like bank 135c which inclined side surface is closer to the display area (DA). The depression 36 is formed with use of a gate insulating film 17, a first interlayer film 19, and a second interlayer film 22, each of which is an inorganic film.

The frame-like bank 135c is configured similarly to the first frame-like bank 135a and the second frame-like bank 135b of the comparative example, and thus is not described here.

The depression 36 is formed so as to have the inclined side surface that forms the taper angle θ3. This is achieved by, for example, carrying out dry etching which uses, as a mask, a resist film provided in a predetermined shape on the second interlayer film 22.

The taper angle θ3 can be set as appropriate, within a range which avoids a break occurring in the first sealing film 28 when the first sealing film 28 is formed.

As illustrated in (b) of FIG. 6, the first sealing film 28, which is an inorganic film, is formed so as to cover (i) the depression 36 having the at least one inclined side surface that forms the taper angle θ3, which depression 36 is formed with use of the gate insulating film 17, the first interlayer film 19, and the second interlayer film 22 which are inorganic films, (ii) the frame-like bank 135c, which is made from an organic material, and (iii) the second interlayer film 22, which is an inorganic film.

The first sealing film 28 is provided in order to prevent ingress of foreign substances such as water and oxygen into an organic EL element 41. Because the first sealing film 28 is formed so as to conform to the depression 36, there is an increase in the area of contact between the first sealing film 28 and inorganic films. This makes it possible to prevent or reduce separation of the first sealing film 28 from the frame-like bank 135c caused by frequent flexing of the flexible organic EL display device 1b, specifically separation at places where an underlying base film (second interlayer film 22, frame-like bank 135c) changes from an inorganic film to an organic film or vice versa, as seen in the portion F indicated by the dotted lines in (b) of FIG. 6.

In this way, separation of the first sealing film 28 from the frame-like bank 135c is prevented or reduced as seen in the portion F indicated by the dotted lines in (b) of FIG. 6. As such, providing the second sealing layer 29 and the third sealing film 30 (not illustrated) above the first sealing film 28 makes it possible to achieve the flexible organic EL display device 1b having even higher reliability.

Discussed in Embodiment 2 is an example in which the depression 36 is formed with use of the gate insulating film 17, the first interlayer film 19, and the second interlayer film 22, which are inorganic films. Note, however, that this is a non-limiting example. The depression 36 may be formed with use of a moisture-proof layer 14, the gate insulating film 17, the first interlayer film 19, and the second interlayer film 22, which are inorganic films. The depression 36 may be formed with use of the first interlayer film 19 and the second interlayer film 22. The depression 36 may be formed with use of only the second interlayer film 22.

FIG. 7 is a diagram schematically illustrating a variation of the flexible organic EL display device 1b illustrated in FIG. 6.

The flexible organic EL display device 1b illustrated in FIG. 6 was configured such that the depression 36 was provided only in a region closer to the display area (DA) than is the frame-like bank 135c. However, it is also possible to employ a configuration in which (i) the depression 36 is provided in a region closer to the display area (DA) than is the frame-like bank 135c, and (ii) the depression 37 is provided in a region outward of the frame-like bank 135c, as with a flexible organic EL display device 1c illustrated in (a) of FIG. 7.

The first sealing film 28 is provided in order to prevent ingress of foreign substances such as water and oxygen into an organic EL element 41. In the flexible organic EL display device 1c, because the first sealing film 28 is formed so as to conform to the depressions 36 and 37, there is an increase in the area of contact between the first sealing film 28 and inorganic films. This makes it possible to prevent or reduce separation of the first sealing film 28 from the frame-like bank 135c caused by frequent flexing of the flexible organic EL display device 1c, specifically separation at places where an underlying base film (second interlayer film 22, frame-like bank 135c) changes from an inorganic film to an organic film or vice versa, as seen in the portions G and H indicated by the dotted lines in (a) of FIG. 7.

In this way, separation of the first sealing film 28 from the frame-like bank 135c is prevented or reduced as seen in the portions G and H indicated by the dotted lines in (a) of FIG. 7. As such, providing the second sealing layer 29 and the third sealing film 30 (not illustrated) above the first sealing film 28 makes it possible to achieve the flexible organic EL display device 1c having even higher reliability.

It is also possible to employ a configuration in which the depression 37 is provided only in a region outward of the frame-like bank 135c, as with a flexible organic EL display device 1d illustrated in (b) of FIG. 7.

The first sealing film 28 is provided in order to prevent ingress of foreign substances such as water and oxygen into an organic EL element 41. In the flexible organic EL display device 1d, because the first sealing film 28 is formed so as to conform to the depression 37, there is an increase in the area of contact between the first sealing film 28 and inorganic films. This makes it possible to prevent or reduce separation of the first sealing film 28 from the frame-like bank 135c caused by frequent flexing of the flexible organic EL display device 1d, specifically separation at places where an underlying base film (second interlayer film 22, frame-like bank 135c) changes from an inorganic film to an organic film or vice versa, as seen in the portion I indicated by the dotted lines in (b) of FIG. 7. This makes it possible to achieve the flexible organic EL display device 1d having high reliability.

### Embodiment 3

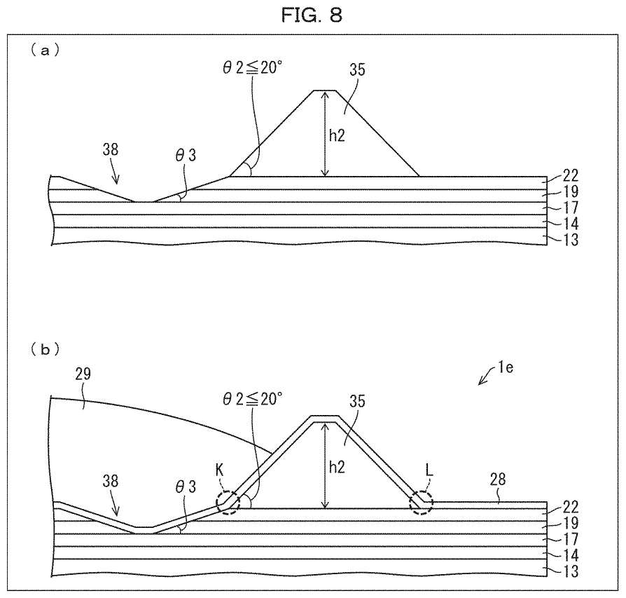

Next, the following description will discuss Embodiment 3 of the disclosure with reference to FIG. 8. Embodiment 3 differs from Embodiment 2 in that Embodiment 3 includes a frame-like bank 35 which is made from an organic material and has at least one inclined side surface that forms a taper angle of not more than 20°. Other than this difference, Embodiment 3 is similar to Embodiment 2. For convenience of description, members of the present embodiment which are identical in function to members illustrated in the drawings for Embodiment 2 are assigned the same reference signs, and descriptions of such members will be omitted.

FIG. 8 is a diagram schematically illustrating a flexible organic EL display device 1e including a depression 38. The depression 38 is provided at the edge of the inclined side surface of the frame-like bank 35 which inclined side surface is closer to a display area (DA). The depression 38 has at least one inclined side surface that forms a taper angle θ3.

(a) of FIG. 8 is a diagram illustrating a state prior to formation of a sealing layer 42. (b) of FIG. 8 is a diagram illustrating a state where a first sealing film 28, a second sealing layer 29, and a third sealing film 30 (not illustrated) which constitute the sealing layer 42 have been formed.

The flexible organic EL display device 1e is achieved as follows. Steps up to and including a step of forming the first sealing film 28, the second sealing layer 29, and the third sealing film 30 (not illustrated) which constitute the sealing layer 42 are carried out on an inflexible glass substrate (not illustrated). After the first sealing film 28, the second sealing layer 29, and the third sealing film 30 are formed, an LLO process is carried out in which the inflexible glass substrate is removed from a PI layer 13, and a flexible film substrate (not illustrated) is affixed to the PI layer 13 via an adhesive layer (not illustrated).

In the flexible organic EL display device 1e, the first sealing film 28 is formed so as to conform to the depression 38. This achieves an increase in the area of contact between the first sealing film 28 and inorganic films. Furthermore, the first sealing film 28 is formed so as to cover the frame-like bank 35, which is made from an organic material and has at least one inclined side surface that forms a taper angle of not more than 20°. This achieves an increase in the area of contact between the first sealing film 28 and the frame-like bank 35.

The first sealing film 28 is provided in order to prevent ingress of foreign substances such as water and oxygen into an organic EL element 41. Because of the above-described increased areas of contact, it is possible to prevent or reduce separation of the first sealing film 28 from the frame-like bank 35 caused by frequent flexing of the flexible organic EL display device 1e, specifically separation at places where the underlying base film (second interlayer film 22, frame-like bank 35) changes from an inorganic film to an organic film or vice versa, as seen in the portions K and L indicated by the dotted lines in (b) of FIG. 8. As such, providing the second sealing layer 29 and the third sealing film 30 (not illustrated) above the first sealing film 28 makes it possible to achieve the flexible organic EL display device 1e having high reliability.

### Embodiment 4

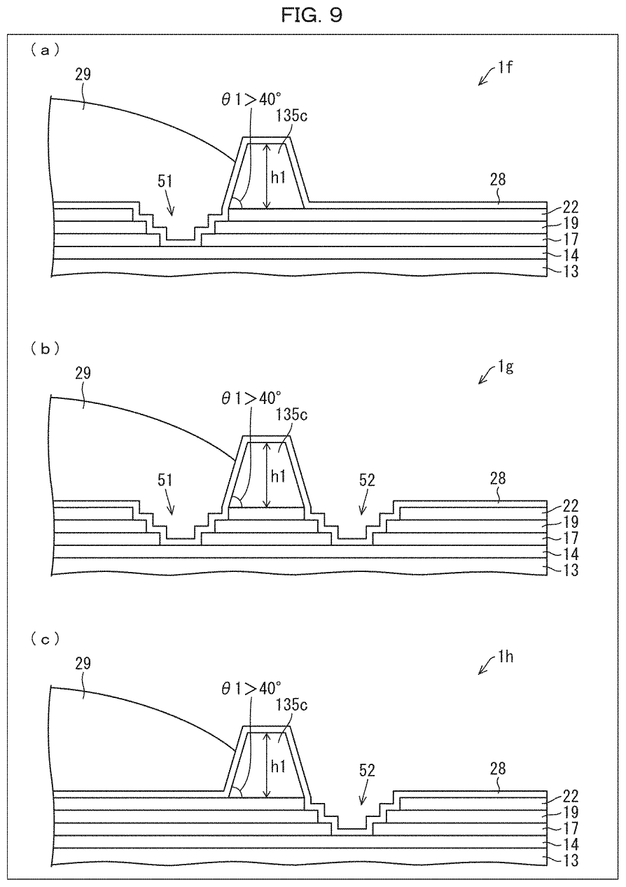

Next, the following description will discuss Embodiment 4 of the disclosure with reference to FIG. 9. Embodiment 4 differs from Embodiment 2 in that depressions 51 and 52 of Embodiment 4 have step-like side surfaces. Other than this difference, Embodiment 4 is similar to Embodiment 2. For convenience of description, members of the present embodiment which are identical in function to members illustrated in the drawings for Embodiment 2 are assigned the same reference signs, and descriptions of such members will be omitted.

(a) of FIG. 9 is a diagram schematically illustrating a flexible organic EL display device 1f, which includes a depression 51 having step-like side surfaces. In the flexible organic EL display device 1f, the depression 51 is provided only in a region closer to a display area (DA) than is a frame-like bank 135c. (b) of FIG. 9 schematically illustrates a flexible organic EL display device 1g, which includes depressions 51 and 52 each having step-like side surfaces. In the flexible organic EL display device 1g, the depression 51 is provided in a region closer to a display area (DA) than is a frame-like bank 135c, and the depression 52 is provided in a region outward of the frame-like bank 135c. (c) of FIG. 9 is a diagram schematically illustrating a flexible organic EL display device 1h, which includes a depression 52 having step-like side surfaces. In the flexible organic EL display device 1h, the depression 52 is provided only in a region outward of a frame-like bank 135c.

Discussed in Embodiment 4 is an example in which the depressions 51 and/or 52 are formed with use of a gate insulating film 17, a first interlayer film 19, and a second interlayer film 22, which are inorganic films. Note, however, that this is a non-limiting example. The depressions 51 and/or 52 may be formed with use of a moisture-proof layer 14, the gate insulating film 17, the first interlayer film 19, and the second interlayer film 22, which are inorganic films. The depressions 51 and/or 52 may be formed with use of the first interlayer film 19 and the second interlayer film 22.

The depressions 51 and/or 52 having the step-like side surfaces can be formed by providing respective openings (slits) in inorganic films such that the opening in a lower layer is smaller than the opening in a higher layer.

The effects of the depression 51 having the step-like side surfaces are similar to those of the depression 36 of Embodiment 2, and thus are not described here. Similarly, the effects of the depression 52 having the step-like side surfaces are similar to those of the depression 37 of Embodiment 2, and thus are not described here.

### Embodiment 5

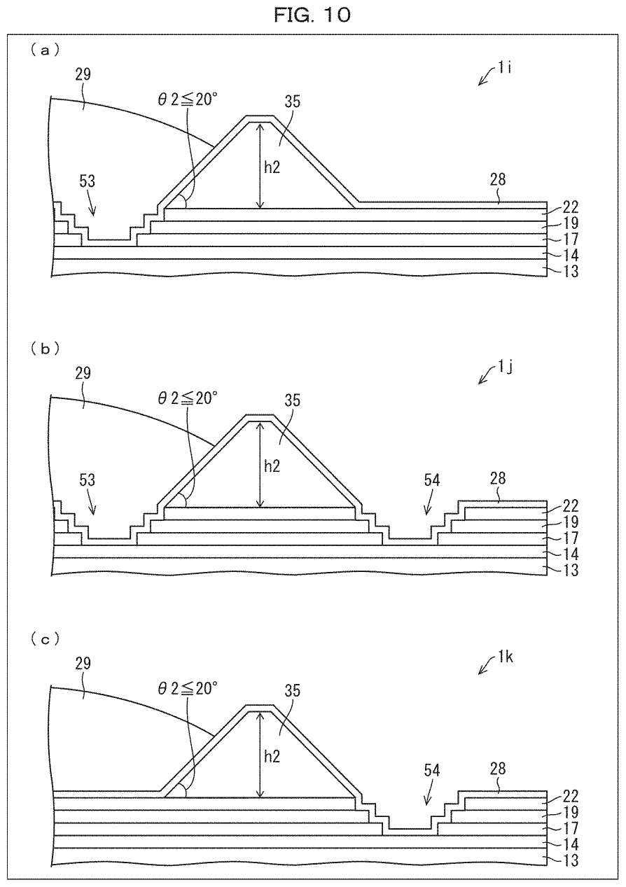

Next, the following description will discuss Embodiment 5 of the disclosure with reference to FIG. 10. Embodiment 5 differs from Embodiment 4 in that Embodiment 5 includes a frame-like bank 35 which is made from an organic material and has at least one inclined side surface that forms a taper angle of not more than 20°. Other than this difference, Embodiment 5 is similar to Embodiment 4. For convenience of description, members of the present embodiment which are identical in function to members illustrated in the drawings for Embodiment 4 are assigned the same reference signs, and descriptions of such members will be omitted.

(a) of FIG. 10 is a diagram schematically illustrating a flexible organic EL display device 1i, which includes a depression 53 having step-like side surfaces. In the flexible organic EL display device 1i, the depression 53 is provided only in a region closer to a display area (DA) than is a frame-like bank 35. (b) of FIG. 10 schematically illustrates a flexible organic EL display device 1j, which includes depressions 53 and 54 each having step-like side surfaces. In the flexible organic EL display device 1j, the depression 53 is provided in a region closer to a display area (DA) than is a frame-like bank 35, and the depression 54 is provided in a region outward of the frame-like bank 35. (c) of FIG. 10 is a diagram schematically illustrating a flexible organic EL display device 1k, which includes a depression 54 having step-like side surfaces. In the flexible organic EL display device 1k, the depression 54 is provided only in a region outward of a frame-like bank 35.

The effects of the frame-like bank 35, which is made from an organic material and has at least one inclined side surface that forms a taper angle of not more than 20°, have been described in Embodiment 1. The effects of the depression 53 having step-like side surfaces are similar to those of the depression 36 of Embodiment 2. The effects of the depression 54 having step-like side surfaces are similar to those of the depression 37 described in Embodiment 2. As such, these effects are not described here.

### Embodiment 6

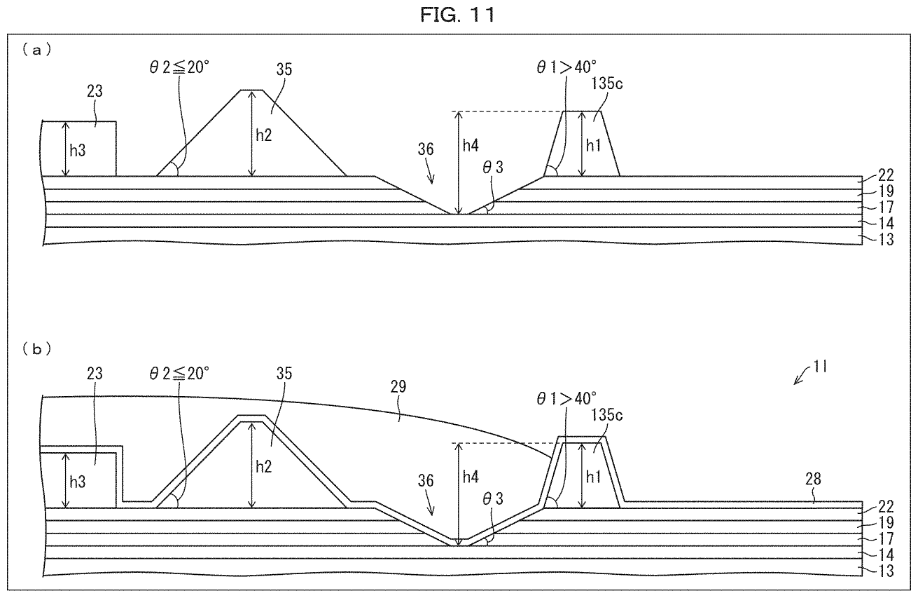

Next, the following description will discuss Embodiment 6 of the disclosure with reference to FIG. 11. Embodiment 6 differs from Embodiments 1 to 5 in that Embodiment 6 includes a frame-like bank 35 (second frame-like bank), a frame-like bank 135c, and a depression 36. The frame-like bank 35 is made from an organic material and has at least one inclined side surface that forms a taper angle of not more than 20°. The frame-like bank 135c has two inclined side surfaces that each form a taper angle θ1 greater than 40° (θ1>40°). The depression 36 is provided between the frame-like bank 35 and the frame-like bank 135c, at an edge of one of the inclined side surfaces of the frame-like bank 135c. The depression 36 has at least one inclined side surface that forms a taper angle θ3. Other than these differences, Embodiment 6 is similar to Embodiments 1 to 5. For convenience of description, members of the present embodiment which are identical in function to members illustrated in the drawings for Embodiments 1 to 5 are assigned the same reference signs, and descriptions of such members will be omitted.

(a) of FIG. 11 is a diagram illustrating a state prior to formation of a sealing layer 42. (b) of FIG. 11 is a diagram illustrating a state where a first sealing film 28, a second sealing layer 29, and a third sealing film 30 (not illustrated) which constitute the sealing layer 42 have been formed.

A flexible organic EL display device 11 is achieved as follows. Steps up to and including a step of forming the first sealing film 28, the second sealing layer 29, and the third sealing film 30 (not illustrated) which constitute the sealing layer 42 are carried out on an inflexible glass substrate (not illustrated). After the first sealing film 28, the second sealing layer 29, and the third sealing film 30 are formed, an LLO process is carried out in which the inflexible glass substrate is removed from a PI layer 13, and a flexible film substrate (not illustrated) is affixed to the PI layer 13 via an adhesive layer (not illustrated).

As illustrated in (a) and (b) of FIG. 11, the frame-like bank 35 and the organic interlayer film 23 are formed such that a height h2 of the frame-like bank 35 is greater than a thickness h3 of an organic interlayer film 23 (see FIG. 1). Furthermore, the frame-like bank 35, the frame-like bank 135c, the depression 36, and the organic interlayer film 23 are formed such that a height h4, which is the sum of (i) a height h1 of the frame-like bank 135c and (ii) a maximum depth of the depression 36, is greater than the thickness h3 of the organic interlayer film 23.

In the flexible organic EL display device 11, the first sealing film 28 is formed so as to conform to (i) the frame-like bank 35, which is made of an organic material and has at least one inclined side surface that forms a taper angle of not more than 20°, and (ii) the depression 36. As such, there is an increase in the area of contact between the first sealing film 28 and the frame-like bank 35, and an increase in the area of contact between the first sealing film 28 and inorganic films.

The first sealing film 28 is provided in order to prevent ingress of foreign substances such as water and oxygen into an organic EL element 41. Because of the above-described increased areas of contact, it is possible to prevent or reduce separation of the first sealing film 28 from the frame-like bank 35 and the frame-like bank 135c caused by frequent flexing of the flexible organic EL display device 11, specifically separation at places where the underlying base film (frame-like bank 35, second interlayer film 22, frame-like bank 135c) changes from an inorganic film to an organic film or vice versa. As such, providing the second sealing layer 29 and the third sealing film 30 (not illustrated) above the first sealing film 28 makes it possible to achieve the flexible organic EL display device 11 having high reliability.

Aspects of the disclosure can also be expressed as follows:

In order to solve the above-described problem, a display device in accordance with Aspect 1 of the disclosure includes: a substrate having (i) a display area in which an active element and a display element are provided and (ii) a non-display area which is provided outside the display area; one or more inorganic films being provided in the display area and the non-display area in a manner so as to cover a semiconductor layer of the active element; a frame-like bank which (i) is made from an organic material, (ii) is provided in the non-display area, above the one or more inorganic films, in a manner so as to surround the display area, and (iii) has two inclined side surfaces, at least one of which forms a taper angle of not more than 20°; and a first sealing film, which is an inorganic film, being provided in the display area and the non-display area in a manner so as to cover the frame-like bank.

The first sealing film, which is an inorganic film, is provided in order to prevent ingress of foreign substances such as water and oxygen into the display element. With the above configuration, the first sealing film is provided so as to cover the frame-like bank, which is made from an organic material and has at least one inclined side surface that forms a taper angle of not more than 20°. As such, the above configuration achieves an increase in the area of contact between the first sealing film and the frame-like bank. This makes it possible to prevent or reduce separation of the first sealing film from the frame-like bank, which separation is caused by frequent flexing of the display device. The above configuration therefore makes it possible to achieve a display device having high reliability.

A display device in accordance with Aspect 2 of the disclosure includes: a substrate having (i) a display area in which an active element and a display element are provided and (ii) a non-display area which is provided outside the display area; one or more inorganic films being provided in the display area and the non-display area in a manner so as to cover a semiconductor layer of the active element; a frame-like bank which (i) is made from an organic material, (ii) is provided in the non-display area, above the one or more inorganic films, in a manner so as to surround the display area, and (iii) has two inclined side surfaces; and a first sealing film, which is an inorganic film, being provided in the display area and the non-display area in a manner so as to cover the frame-like bank, a depression being formed in the one or more inorganic films at an edge of at least one of the two inclined side surfaces, the first sealing film conforming to the depression.

The first sealing film, which is an inorganic film, is provided in order to prevent ingress of foreign substances such as water and oxygen into the display element. With the above configuration, the first sealing film is provided so as to (i) cover the frame-like bank, which is made from an organic material, and (ii) conform to the depression formed in the one or more inorganic films. As such, the above configuration achieves an increase in the area of contact between the first sealing film and the one or more inorganic films. This makes it possible to prevent or reduce separation of the first sealing film from the frame-like bank, which separation is caused by frequent flexing of the display device. The above configuration therefore makes it possible to achieve a display device having high reliability.

In Aspect 3 of the disclosure, the display device in accordance with Aspect 2 may be configured to further include: a resin layer; and a moisture-proof layer, which is an inorganic film, being provided in a manner so as to cover the resin layer, the first sealing film being in contact with the moisture-proof layer in the depression.

The above configuration makes it possible to achieve a display device having high reliability.

In Aspect 4 of the disclosure, the display device in accordance with Aspect 1 may be configured such that: the one or more inorganic films are provided in a manner so as to be flat in the non-display area; and each of the two inclined side surfaces forms a respective taper angle of not more than 20°.

The above configuration makes it possible to further increase the area of contact between the first sealing film and the frame-like bank.

In Aspect 5 of the disclosure, the display device in accordance with Aspect 1 may be configured such that a depression is formed in the one or more inorganic films at an edge of at least one of the two inclined side surfaces.

The above configuration makes it possible to increase the area of contact between the first sealing film and the one or more inorganic films.

In Aspect 6 of the disclosure, the display device in accordance with Aspect 2 or 3 may be configured such that at least one of the two inclined side surfaces forms a taper angle of not more than 20°.

The above configuration makes it possible to further increase the area of contact between the first sealing film and the frame-like bank.

In Aspect 7 of the disclosure, the display device in accordance with any one of Aspects 2, 3, 5, and 6 may be configured such that the depression is formed only in a region closer to the display area than is the frame-like bank.

The above configuration makes it possible to achieve a display device having high reliability.

In Aspect 8 of the disclosure, the display device in accordance with any one of Aspects 2, 3, 5, and 6 may be configured such that the depression is formed only in a region outward of the frame-like bank.

The above configuration makes it possible to achieve a display device having high reliability.

In Aspect 9 of the disclosure, the display device in accordance with any one of Aspects 2, 3, 5, and 6 may be configured such that the depression includes a first depression and a second depression, the first depression being formed in a region closer to the display area than is the frame-like bank, the second depression being formed in a region outward of the frame-like bank.

The above configuration makes it possible to achieve a display device having high reliability.

In Aspect 10 of the disclosure, the display device in accordance with any one Aspects 2, 3, 5, 6, 7, 8, and 9 may be configured such that the depression has an inclined side surface.

The above configuration makes it possible to achieve a display device having high reliability.

In Aspect 11 of the disclosure, the display device in accordance with any one of Aspects 2, 3, 5, 6, 7, 8, and 9 may be configured such that: the one or more inorganic films include two or more inorganic films; and the depression has a step-like side surface.

The above configuration makes it possible to achieve a display device having high reliability.

In Aspect 12 of the disclosure, the display device in accordance with Aspect 2 may be configured to further include: a second frame-like bank which (i) is made from an organic material, (ii) is provided in the non-display area, above the one or more inorganic films, in a manner so as to surround the display area and be closer to the display area than is the frame-like bank, and (iii) has two inclined side surfaces, at least one of which forms a taper angle of not more than 20°; and an organic interlayer film provided above the one or more inorganic films, the depression being formed between the frame-like bank and the second frame-like bank, the frame-like bank, the second frame-like bank, the depression, and the organic interlayer film being provided such that (i) the second frame-like bank has a height which is greater than a thickness of the organic interlayer film and (ii) a sum of (a) a height of the frame-like bank and (b) a maximum depth of the depression is greater than the thickness of the organic interlayer film, the first sealing film being provided, in the display area and the non-display area, in a manner so as to (i) cover the frame-like bank and the second frame-like bank and (ii) conform to the depression.

The above configuration makes it possible to achieve a display device having high reliability.

In Aspect 13 of the disclosure, the display device in accordance with any one of Aspects 1 through 12 may be configured such that the one or more inorganic films include a gate insulating film, a first interlayer film, and a second interlayer film.

The above configuration makes it possible to increase the area of contact between the first sealing film and the one or more inorganic films.

In Aspect 14 of the disclosure, the display device in accordance with any one of Aspects 1 through 13 may be configured to further include: a second sealing layer, made from an organic material, which is provided above the first sealing film in a region that (i) is surrounded by the frame-like bank and (ii) includes the display area.

The above configuration makes it possible to achieve a display device having high reliability.

In Aspect 15 of the disclosure, the display device in accordance with Aspect 14 may be configured to further include: a third sealing film, which is an inorganic film, being provided so as to cover the first sealing film and the second sealing layer.

The above configuration makes it possible to achieve a display device having high reliability.

In Aspect 16 of the disclosure, the display device in accordance with any one of Aspects 1 through 15 may be configured such that the substrate is flexible.

The above configuration makes it possible to achieve a flexible display device having high reliability.

In Aspect 17 of the disclosure, the display device in accordance with any one of Aspects 1 through 16 may be configured such that the display element is an organic EL display element.

The above configuration makes it possible to achieve a display device which includes an organic EL display element and has high reliability.

Supplemental Remarks

The disclosure is not limited to the embodiments, but can be altered by a skilled person in the art within the scope of the claims. The disclosure also encompasses, in its technical scope, any embodiment derived by combining technical means disclosed in differing embodiments. Further, it is possible to form a new technical feature by combining the technical means disclosed in the respective embodiments.

### INDUSTRIAL APPLICABILITY

An embodiment of the disclosure can be applied to a display device which includes a display element such as an organic EL display element.

### REFERENCE SIGNS LIST

1 Flexible organic EL display device (display device)
1b through 11 Flexible organic EL display device (display device)
11 Flexible substrate (substrate)
12 Adhesive layer
13 PI layer (polyimide layer)
14 Moisture-proof layer
16 Semiconductor layer
17 Gate insulating film
18 Gate electrode
19 First interlayer film
20 Source electrode
21 Drain electrode
22 Second interlayer film
23 Organic interlayer film
24 First electrode
25 Edge cover
26 Layer including light emitting layer
27 Second electrode
28 First sealing film
29 Second sealing layer
30 Third sealing film
32 Capacitor electrode
33 Wiring
35 Frame-like bank
135a First frame-like bank
135b Second frame-like bank
40 TFT substrate
41 Organic EL element
42 Sealing layer
θ1 through θ3 Taper angle
DA Display area
NDA Non-display area

1. A display device comprising:
a substrate having (i) a display area in which an active element and a display element are provided and (ii) a non-display area which is provided outside the display area;
one or more inorganic films being provided in the display area and the non-display area in a manner so as to cover a semiconductor layer of the active element;
a frame-like bank which (i) is made from an organic material, (ii) is provided in the non-display area, above the one or more inorganic films, in a manner so as to surround the display area, and (iii) has two inclined side surfaces, at least one of which forms a taper angle of not more than 20°; and
a first sealing film, which is an inorganic film, being provided in the display area and the non-display area in a manner so as to cover the frame-like bank.

2. A display device comprising:
a substrate having (i) a display area in which an active element and a display element are provided and (ii) a non-display area which is provided outside the display area;
one or more inorganic films being provided in the display area and the non-display area in a manner so as to cover a semiconductor layer of the active element;
a frame-like bank which (i) is made from an organic material, (ii) is provided in the non-display area, above the one or more inorganic films, in a manner so as to surround the display area, and (iii) has two inclined side surfaces; and
a first sealing film, which is an inorganic film, being provided in the display area and the non-display area in a manner so as to cover the frame-like bank,
a depression being formed in the one or more inorganic films at an edge of at least one of the two inclined side surfaces,
the first sealing film conforming to the depression.

3. The display device as set forth in claim 2, further comprising:
a resin layer; and
a moisture-proof layer, which is an inorganic film, being provided in a manner so as to cover the resin layer,
the first sealing film being in contact with the moisture-proof layer in the depression.

4. The display device as set forth in claim 1, wherein:
the one or more inorganic films are provided in a manner so as to be flat in the non-display area; and
each of the two inclined side surfaces forms a respective taper angle of not more than 20°.

5. The display device as set forth in claim 1, wherein a depression is formed in the one or more inorganic films at an edge of at least one of the two inclined side surfaces.

6. The display device as set forth in claim 2, wherein at least one of the two inclined side surfaces forms a taper angle of not more than 20°.

7. The display device as set forth in claim 2, wherein the depression is formed only in a region closer to the display area than is the frame-like bank.

8. The display device as set forth in claim 2, wherein the depression is formed only in a region outward of the frame-like bank.

9. The display device as set forth in claim 2, wherein the depression includes a first depression and a second depression,
the first depression being formed in a region closer to the display area than is the frame-like bank,
the second depression being formed in a region outward of the frame-like bank.

10. The display device as set forth in claim 2, wherein the depression has an inclined side surface.

11. The display device as set forth in claim 2, wherein:
the one or more inorganic films include two or more inorganic films; and
the depression has a step-like side surface.

12. The display device as set forth in claim 2, further comprising:
a second frame-like bank which (i) is made from an organic material, (ii) is provided in the non-display area, above the one or more inorganic films, in a manner so as to surround the display area and be closer to the display area than is the frame-like bank, and (iii) has two inclined side surfaces, at least one of which forms a taper angle of not more than 20°; and
an organic interlayer film provided above the one or more inorganic films,
the depression being formed between the frame-like bank and the second frame-like bank,
the frame-like bank, the second frame-like bank, the depression, and the organic interlayer film being provided such that (i) the second frame-like bank has a height which is greater than a thickness of the organic interlayer film and (ii) a sum of (a) a height of the frame-like bank and (b) a maximum depth of the depression is greater than the thickness of the organic interlayer film,
the first sealing film being provided, in the display area and the non-display area, in a manner so as to (i) cover the frame-like bank and the second frame-like bank and (ii) conform to the depression.

13. The display device as set forth in claim 1, wherein the one or more inorganic films include a gate insulating film, a first interlayer film, and a second interlayer film.

14. The display device as set forth in claim 1, further comprising:
a second sealing layer, made from an organic material, which is provided above the first sealing film in a region that (i) is surrounded by the frame-like bank and (ii) includes the display area.

15. The display device as set forth in claim 14, further comprising:
a third sealing film, which is an inorganic film, being provided so as to cover the first sealing film and the second sealing layer.

16. The display device as set forth in claim 1, wherein the substrate is flexible.

17. The display device as set forth in claim 1, wherein the display element is an organic EL display element.
